(19) United States
(12) Patent Application Publication
(10) Pub. No.: US 2026/0182462 A1
(43) Pub. Date: Jun. 25, 2026

(54) SEMICONDUCTOR DEVICE AND MANUFACTURING METHOD FOR SEMICONDUCTOR DEVICE

(71) Applicant: Kioxia Corporation, Tokyo (JP)

(72) Inventor: Hideo NUMATA, Shinagawa (JP)

(73) Assignee: Kioxia Corporation, Tokyo (JP)

(21) Appl. No.: 19/308,476

(22) Filed: Aug. 25, 2025

(30) Foreign Application Priority Data
Dec. 19, 2024 (JP) 2024-224177

(51) Int. Cl. H01L 23/00; H01L 21/56; H01L 23/13; H01L 25/065; H10B 80/00

(52) U.S. Cl. CPC H10W 90/00; H10W 70/68; H10B 80/00; H10W 70/09; H10W 70/6528; H10W 74/01; H10W 90/10; H10W 90/24

(57) ABSTRACT

According to one embodiment, a semiconductor device includes a wiring substrate, a stacked body, a sealing member, and a through electrode. The stacked body includes first to third semiconductor chips arranged such that their first surfaces are inclined with respect to a wiring substrate. Each of the first to third semiconductor chips includes an electrode pad on an end part of the first surface. The sealing member that covers the stacked body includes, on a side close to the electrode pad, a third surface that is parallel to a plane in which the electrode pads of at least two of the first to third semiconductor chips are included. The through electrode extends from the electrode pad in a direction perpendicular to the third surface through the sealing member and is connected to the wiring substrate.

### CROSS-REFERENCE TO RELATED APPLICATIONS

This application is based upon and claims the benefit of priority from Japanese Patent Application No. 2024-224177, filed on Dec. 19, 2024, the entire contents of which are incorporated herein by reference.

### FIELD

Embodiments described herein relate generally to a semiconductor device and a manufacturing method for a semiconductor device.

### BACKGROUND

There is a semiconductor package in which a plurality of semiconductor chips is sealed by a sealing member. In a manufacturing process of such a semiconductor package, electrodes for transferring electrical signals to the semiconductor chips are led out on the sealing member.

### BRIEF DESCRIPTION OF THE DRAWINGS

FIG. 1 is a diagram illustrating an example of a configuration of a semiconductor device according to an embodiment;

FIGS. 2a, 2b, and 2c are diagrams sequentially illustrating part of a procedure of a manufacturing method for a semiconductor device according to an embodiment;

FIGS. 3a, 3b, and 3c are diagrams sequentially illustrating part of a procedure of a manufacturing method for a semiconductor device according to an embodiment;

FIGS. 4a and 4b are diagrams sequentially illustrating part of a procedure of a manufacturing method for a semiconductor device according to an embodiment;

FIG. 5Aa, 5Ab, and 5Ac are diagrams sequentially illustrating part of a procedure of a manufacturing method for a semiconductor device according to a first modification example of an embodiment;

FIG. 5B is a diagram sequentially illustrating part of a procedure of a manufacturing method for a semiconductor device according to a first modification example of an embodiment;

FIG. 6Aa, 6Ab, and 6Ac are diagrams sequentially illustrating part of a procedure of a manufacturing method for a semiconductor device according to a second modification example of an embodiment;

FIG. 6B is a diagram sequentially illustrating part of a procedure of a manufacturing method for a semiconductor device according to a second modification example of an embodiment;

FIG. 7Aa to 7Ac are diagrams sequentially illustrating part of a procedure of a manufacturing method for a semiconductor device according to a third modification example of an embodiment;

FIG. 7B is a diagram sequentially illustrating part of a procedure of a manufacturing method for a semiconductor device according to a third modification example of an embodiment;

FIGS. 8a and 8b are diagrams sequentially illustrating part of a procedure of a manufacturing method for a semiconductor device according to a fourth modification example of an embodiment;

FIG. 9A is a diagram sequentially illustrating part of a procedure of a manufacturing method for a semiconductor device according to a fifth modification example of an embodiment;

FIG. 9B is a diagram sequentially illustrating part of a procedure of a manufacturing method for a semiconductor device according to a fifth modification example of an embodiment;

FIGS. 10a and 10b are diagrams sequentially illustrating part of a procedure of a manufacturing method for a semiconductor device according to a sixth modification example of an embodiment;

FIG. 11Aa and 11Ab are diagrams sequentially illustrating part of a procedure of a manufacturing method for a semiconductor device according to a sixth modification example of an embodiment;

FIG. 11B is a diagram sequentially illustrating part of a procedure of a manufacturing method for a semiconductor device according to a sixth modification example of an embodiment; and

FIGS. 12a, 12b, and 12c are diagrams illustrating part of a procedure of a manufacturing method for a semiconductor device according to a comparative example.

### DETAILED DESCRIPTION

According to one embodiment, a semiconductor device includes a wiring substrate, a stacked body, a sealing member, and a through electrode. The stacked body includes first to third semiconductor chips. Each of the first to third semiconductor chips include a first surface and a second surface on a side opposite to the first surface. Each of the first to third semiconductor chips is arranged to cause the first surface to face the wiring substrate with an inclination. Each of the first to third semiconductor chips includes an electrode pad on an end part of the first surface. The second semiconductor chip is stacked directly above the first semiconductor chip in a first direction along the wiring substrate without overlap between the second surface of the second semiconductor chip and the electrode pad of the first semiconductor chip. The third semiconductor chip is stacked directly above the second semiconductor chip in the first direction without overlap between the second surface of the third semiconductor chip and the electrode pad of the second semiconductor chip. The sealing member covers the stacked body and includes a third surface on a side close to the electrode pad of the stacked body. The third surface is parallel to a plane in which the electrode pads of at least two of the first to third semiconductor chips are included. The through electrodes extend from the electrode pad in a second direction perpendicular to the third surface through the sealing member and are connected to the wiring substrate.

Hereinafter, a semiconductor device and a manufacturing method for the semiconductor device according to the embodiments will be described in detail with reference to the accompanying drawings. Note that the present invention is not limited by these embodiments.

### Embodiments

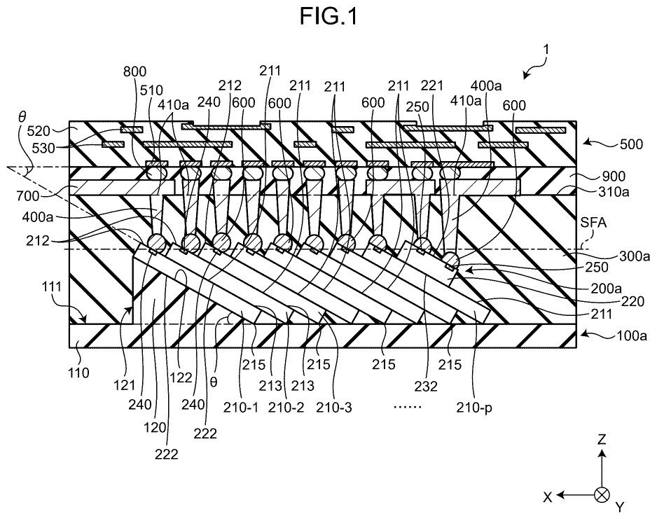

An embodiment will be described in detail with reference to FIGS. 1 to 4b.

A semiconductor device of the embodiment has a flat plate shape in which a sealing member for sealing stacked semiconductor chips is bonded to a wiring substrate. In the present specification, a thickness direction of the flat plate of the semiconductor device is defined as a Z direction.

While details will be described later, each of the semiconductor chips is arranged with an inclination of an angle θ with respect to the wiring substrate extending in a predetermined direction intersecting the Z direction, and is stacked in the predetermined direction. The predetermined direction in which the semiconductor chips are stacked is defined as an X direction. Thus, the X direction is a direction along the wiring substrate. A direction intersecting both the Z direction and the X direction is defined as a Y direction. A direction along the Z direction is defined as an up-down direction, in which a side of a support member to be described later is defined as a lower side and a side of the wiring substrate is defined as an upper side. A direction indicated by the arrow of each axis is defined as a positive direction, and a direction opposite to a head of the arrow of each axis is defined as a negative direction. The positive and negative direction of X is an example of the first direction, and the positive and negative directions of Z are examples of a second direction.

### Configuration Example of Semiconductor Device

FIG. 1 is a diagram illustrating an example of a configuration of a semiconductor device 1 according to the embodiment. FIG. 1 is a sectional view taken along the XZ plane of the semiconductor device 1. Note that, in consideration of visibility, in FIG. 1, hatching for some configurations such as a plurality of semiconductor chips 210 and a semiconductor chip 220 is omitted.

As illustrated in FIG. 1, the semiconductor device 1 includes a support member 100a, a stacked body 200a, a sealing member 300a, a vertical wire 400a, and a wiring substrate 500.

The stacked body 200a is disposed on the upper surface of the support member 100a. The stacked body 200a has a configuration in which semiconductor chips 210-1 to 210-p (where p is an integer of three or more) and the semiconductor chip 220 are stacked. The stacked body 200a is covered with the sealing member 300a. The vertical wire 400a extending from the stacked body 200a is exposed on a surface 310a of the sealing member 300a. The wiring substrate 500 is disposed at a position facing the stacked body 200a. Thus, the wiring substrate 500 and the support member 100a face each other with the stacked body 200a interposed therebetween. The wiring substrate 500 is electrically connected to the vertical wire 400a.

Hereinafter, in a case where the semiconductor chips 210-1 to 210-p are not individually distinguished, each of the semiconductor chips 210-1 to 210-p may be referred to as a “semiconductor chip 210”.

The support member 100a includes a plate-like part 110 extending along the XY plane, and a base part 120 protruding upward from a plate surface 111 of the plate-like part 110. On the plate surface 111 of the plate-like part 110, each of the semiconductor chips 210 and the semiconductor chip 220, which constitute the stacked body 200a, is disposed in an inclined manner. The plate surface 111 supports each of the semiconductor chips 210 and the semiconductor chip 220. The plate-like part 110 and the base part 120 are made of, for example, a resin material.

The base part 120 includes a vertical surface 121 facing the positive direction side of X, and an inclined surface 122 facing the negative direction side of X. The vertical surface 121 extends substantially vertically upward from the plate surface 111. In addition, the inclined surface 122 extends obliquely upward from the plate surface 111 at a position on the negative direction side of X axis relative to the vertical surface 121, and is in contact with the vertical surface 121 at the upper end part. In other words, the inclined surface 122 is a surface descending from the upper end part, which is a connection end with the vertical surface 121, toward the plate surface 111. Among the semiconductor chips 210 and the semiconductor chip 220 which are stacked, the semiconductor chip located farthest on the positive direction side of X is supported by the inclined surface 122, and thereby the inclination of each of the semiconductor chips 210 and the semiconductor chip 220 is maintained.

In one example, an angle θ between the plate surface 111 and the inclined surface 122 is in a range of 3° to 30°, both inclusive. Each of the semiconductor chips 210 and the semiconductor chip 220 is inclined at the angle θ within the above-described range with respect to the plate surface 111. Moreover, by setting the angle θ within the above-described range, the height in the Z direction of each of the semiconductor chips 210 and the semiconductor chip 220, which are arranged in an inclined manner, can be set to be equal to or less than a predetermined value. The angle θ is an example of the angle of inclination.

As described above, the wiring substrate 500 and the support member 100a face each other with the stacked body 200a interposed therebetween. Therefore, the inclined surface 122 also forms the angle θ with respect to the wiring substrate 500. Thus, each of the semiconductor chips 210 and the semiconductor chip 220 arranged at the angle θ with respect to the plate surface 111 is also arranged at the angle θ with respect to the wiring substrate 500. Hereinafter, in the present specification, for convenience of description, the inclination of each configuration of the semiconductor chips 210 and the semiconductor chip 220 will be described with reference to the plate surface 111. However, being inclined with respect to the plate surface 111 means that the same inclination is also applied with respect to the wiring substrate 500.

Each of the semiconductor chips 210 is formed in a rectangular flat plate shape. The semiconductor chips 210 each include a main surface 211 as a first surface and a back surface 222 on a side opposite to the main surface 211. The main surface 211 and the back surface 222 each have a planar shape that is not curved, bent, or the like. Each of the semiconductor chips 210 is arranged on the plate surface 111 such that the back surface 222 is located closer to the inclined surface 122 than the main surface 211. The back surface 222 is an example of the second surface.

Each of the semiconductor chips 210 includes a semiconductor element (not illustrated) on the main surface 211 as the first surface. The semiconductor element is, for example, a nonvolatile memory such as a NAND flash memory. An electrode pad 240 for electrically leading out the semiconductor element is provided at an end part 212 of the main surface 211 of each of the semiconductor chips 210. Note that each of the semiconductor chips 210 is not limited to a chip having a NAND flash memory or the like.

In the present embodiment, the length of each side constituting the main surface 211 of each semiconductor chip 210 is common to the corresponding side of each of the semiconductor chips 210.

Each of the semiconductor chips 210 is disposed on the plate surface 111 in an orientation in which the end part 212 side where the electrode pad 240 is provided is an upper side and an end part 213 on a side opposite to the end part 212 is a lower side. The end part 212 is an example of the first end part, and the end part 213 is an example of the second end part.

Among the semiconductor chips 210, the semiconductor chip 210-1 serving as the first semiconductor chip is disposed on the inclined surface 122. The back surface 222 of the semiconductor chip 210-1 is in contact with the inclined surface 122. As a result, the main surface 211 of the semiconductor chip 210-1 forms the angle θ with respect to the plate surface 111. A lower end part 215 of the back surface 222 of the semiconductor chip 210-1 is in contact with the plate surface 111.

The semiconductor chip 210-2 serving as the second semiconductor chip is stacked directly above the semiconductor chip 210-1, that is, on the negative direction side of X. The main surface 211 of the semiconductor chip 210-1 is in contact with the back surface 222 of the semiconductor chip 210-2. As a result, the main surface 211 of the semiconductor chip 210-2 also forms the angle θ with respect to the plate surface 111.

The semiconductor chip 210-2 is stacked to be shifted toward the end part 213 with respect to the semiconductor chip 210-1 without overlap between the back surface 222 of the semiconductor chip 210-2 and the electrode pad 240 of the semiconductor chip 210-1. The lower end part 215 of the back surface 222 of the semiconductor chip 210-2 is in contact with the plate surface 111.

In addition, the semiconductor chip 210-3 serving as the third semiconductor chip is stacked directly above the semiconductor chip 210-2, namely, stacked on the negative direction side of X. The main surface 211 of the semiconductor chip 210-2 is in contact with the back surface 222 of the semiconductor chip 210-3. As a result, the main surface 211 of the semiconductor chip 210-3 forms the angle θ with respect to the plate surface 111.

The semiconductor chip 210-3 is stacked to be shifted toward the end part 213 with respect to the semiconductor chip 210-2 without overlap between the back surface 222 of the semiconductor chip 210-3 and the electrode pad 240 of the semiconductor chip 210-2. The lower end part 215 of the back surface 222 of the semiconductor chip 210-3 is in contact with the plate surface 111.

Similarly, the remaining semiconductor chips 210 of the semiconductor chips 210 are sequentially stacked on the semiconductor chip 210-3. In this manner, the semiconductor chips 210 are stacked such that each main surface 211 is inclined at the angle θ with respect to the plate surface 111 and each semiconductor chip 210 is shifted toward the end part 213 with respect to the semiconductor chip 210 located on the layer directly below, that is, on the positive direction side of X.

The electrode pads 240 provided on the main surfaces 211 of the respective semiconductor chips 210-1 to 210-3 are arranged at substantially the same height position when viewed from the plate surface 111. Thus, each of the electrode pads 240 of the semiconductor chips 210-1 to 210-3 is included on the same plane along the XY plane.

As described above, the length of each side constituting the main surface 211 is common to each corresponding side of the semiconductor chips 210. Thus, the length of one side of the main surface 211 of the semiconductor chips 210-1 to 210-3 along the XZ plane is substantially equal. Each of the semiconductor chips 210-1 to 210-3 is similarly shifted until each semiconductor chip comes into contact with the plate surface 111, and thereby the electrode pads 240 are arranged substantially parallel to the plate surface 111.

Meanwhile, if the length of one side of the main surface 211 of the semiconductor chips 210-1 to 210-3 along the XZ plane differs from chip to chip, the amount of shift of each of the semiconductor chips 210-1 to 210-3 with respect to the semiconductor chip 210 located on the layer directly below is adjusted such that the electrode pads 240 are arranged at substantially the same height position when viewed from the plate surface 111.

Hereinafter, a plane including each of the electrode pads 240 of the semiconductor chips 210-1 to 210-3 is referred to as a plane SFA. The plane SFA is a plane parallel to the XY plane.

Note that it is not always necessary for all the electrode pads 240 of the semiconductor chips 210-1 to 210-3 to be included in the plane SFA, and it is sufficient that the electrode pads 240 of at least two semiconductor chips 210 are included in the plane SFA.

The semiconductor chip 220 is, for example, a controller chip that controls the NAND flash memory or the like provided in the semiconductor chips 210. An electrode pad 250 is provided at each of both end parts of a main surface 221 of the semiconductor chip 220.

The semiconductor chip 220 is formed in a flat plate shape and includes the main surface 221 as the first surface, and a back surface 232 on a side opposite to the main surface 221. The semiconductor chip 220 is disposed such that the back surface 232 is in contact with the main surface 211 of the uppermost semiconductor chip 210. The semiconductor chip 220 is disposed to be shifted with respect to the uppermost semiconductor chip 210 such that at least one electrode pad 250 among the electrode pads 250 provided at both end parts of the main surface 221 is included in the plane SFA.

However, it is not always necessary for all the electrode pads 240 and either of the two electrode pads 250 to be included in the plane SFA. For example, it is sufficient that at least two or more electrode pads among the electrode pads 240 and 250 are included in the plane SFA.

Note that an adhesive layer (not illustrated) may be provided on the lower surface of each of the semiconductor chips 210 and the semiconductor chip 220.

Metal bumps 600 are connected to the electrode pads 240 and 250. The metal bump 600 includes, for example, a metal such as copper (Cu). The metal bump 600 is formed using, for example, a thermocompression bonding technique, an ultrasonic bonding technique, or the like. The vertical wire 400a to be described later is connected to the metal bump 600.

The sealing member 300a seals the entire stacked body 200a including the metal bump 600. The sealing member 300a includes, for example, a thermosetting resin material such as an epoxy resin or an acrylic resin. The sealing member 300a includes the surface 310a along the XY plane on a side close to the stacked body 200a where the metal bumps 600 are connected, that is, on the electrode pad 240 side. Thus, the surface 310a is also a surface parallel to the plane SFA.

The surface 310a is also a surface parallel to the plate surface 111 along the XY plane. As described above, each of the semiconductor chips 210 and the semiconductor chip 220 is inclined at the angle θ with respect to the plate surface 111. In other words, the surface 310a extends in a direction intersecting a direction in which each of the main surfaces 211 of the semiconductor chips 210 and the main surface 221 of the semiconductor chip 220 extends. The surface 310a is an example of the third surface.

The vertical wire 400a is connected to one of the metal bumps 600 at the lower end part thereof, extends in the positive direction of Z through the sealing member 300a, and is exposed on the surface 310a of the sealing member 300a at an upper end part 410a thereof. As a result, the semiconductor chips 210 and the semiconductor chip 220 are electrically led out onto the surface 310a. The vertical wire 400a includes, for example, a metal such as copper (Cu). The vertical wire 400a is an example of the through electrode. In addition, the vertical wire 400a may also be a vertical electrode or a via, in addition to the through electrode.

As a result, each vertical wire 400a is formed to have substantially the same length. This is because, as described above, the plane SFA, which includes the electrode pads 240 and 250, and the surface 310a are formed to be substantially parallel.

A wiring layer 700 is connected to the upper end parts 410a of the vertical wires 400a. The wiring layer 700 has a wiring pattern extending in the XY plane on the surface 310a. The wiring layer 700 includes, for example, a metal such as copper (Cu). Metal bumps 800 are connected to the upper surface of the wiring layer 700. The metal bump 800 is formed using, for example, a thermocompression bonding technique, an ultrasonic bonding technique, or the like. The metal bump 800 includes, for example, a metal such as copper (Cu).

With such a wiring layer 700, the upper end part 410a of the vertical wire 400a is further led out onto the metal bump 800. As a result, although not illustrated in the drawings, it is possible to make the exposed position of the upper end part 410a of the vertical wire 400a on the surface 310a different from the lead-out position of the vertical wire 400a on the metal bump 800 as necessary.

The wiring substrate 500 extending along the XY plane is provided above the metal bumps 800. The metal bump 800 is connected to the wiring layer 700 at the lower end part thereof, and is connected to an electrode 510, which is provided on the lower surface of the wiring substrate 500, at the upper end part thereof. As a result, the wiring substrate 500 is electrically connected to the semiconductor chips 210 and the semiconductor chip 220.

The periphery of the metal bump 800 is filled with an adhesive 900. The adhesive 900 is, for example, called an underfill agent and includes a liquid epoxy resin or the like. The adhesive 900 is disposed between the lower surface of the wiring substrate 500 and the surface 310a of the sealing member 300a. As a result, a connection part between the wiring layer 700 and the metal bump 800, and a connection part between the metal bump 800 and the electrode 510 of the wiring substrate 500 are protected.

The wiring substrate 500 has a configuration in which an insulating layer 520 and a conductive layer 530 are alternately stacked multiple times. The wiring substrate 500 also includes electrodes 510 exposed on the lower surface thereof. The insulating layer 520 includes, for example, carbon fibers, glass fibers, or aramid fibers impregnated with a thermosetting resin such as epoxy resin before curing. The conductive layer 530 is made of, for example, a metal such as copper (Cu). The conductive layer 530 has a wiring pattern extending along the XY plane and is connected to the electrodes 510.

Note that, although not illustrated in the drawings, a solder ball connected to the conductive layer 530 may be disposed on the upper surface of the wiring substrate 500. By connecting the solder ball to, for example, a motherboard (not illustrated), the semiconductor device 1 can be mounted on the motherboard or the like.

### Manufacturing Method for Semiconductor Device

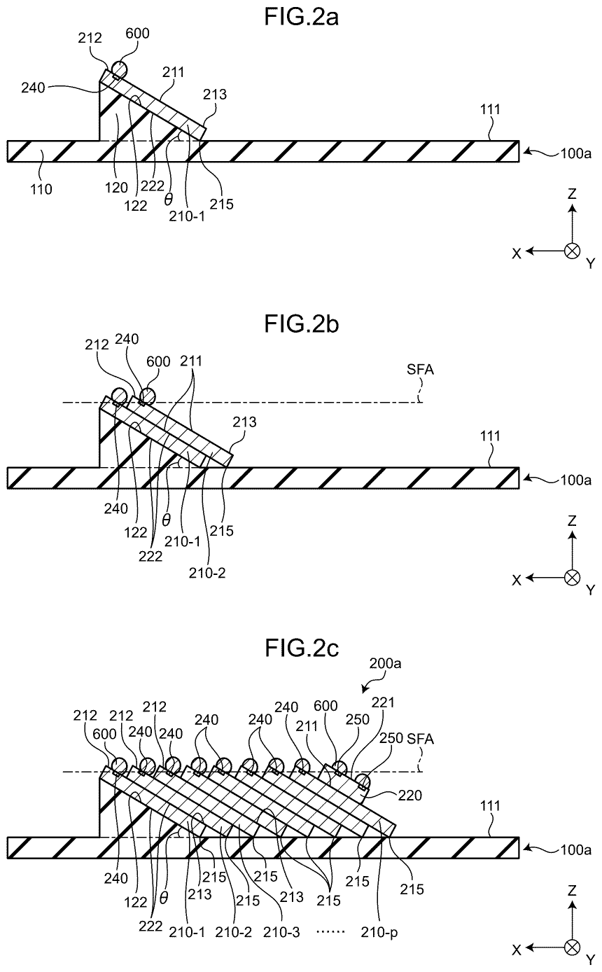

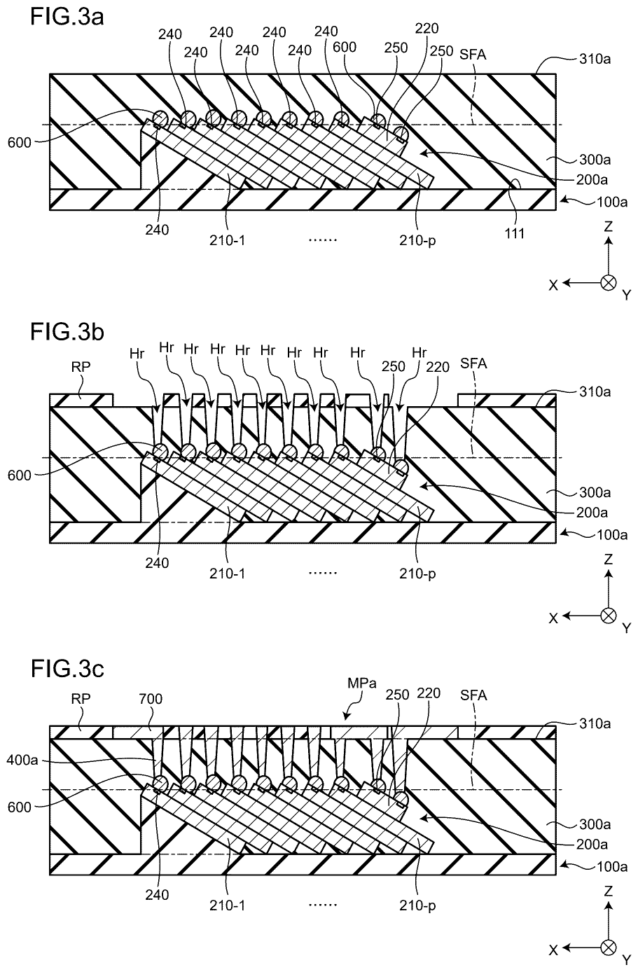

Next, a manufacturing method for the semiconductor device 1 according to the embodiment will be described with reference to FIGS. 2a, 2b, 2c, 3a, 3b, 3c 4a, and 4b. FIGS. 2a to 4b are diagrams sequentially illustrating part of a procedure of the manufacturing method for the semiconductor device 1 according to the embodiment.

First, a procedure for forming the stacked body 200a will be described with reference to FIGS. 2a to 2c.

Prior to the processing of FIG. 2a, the metal bump 600 is disposed on each of the electrode pads 240 provided at the end parts 212 of the main surfaces 211 of the semiconductor chips 210, and on each of the electrode pads 250 provided at both end parts of the main surface 221 of the semiconductor chip 220. The metal bump 600 protects the electrode pads 240 and 250 from laser light or the like when a contact hole Hr is formed at a later stage.

However, the timing at which the metal bump 600 is disposed is not limited thereto. For example, the metal bump 600 may be disposed after the stacked body 200a is formed.

As illustrated in FIG. 2a, the support member 100a for placing the stacked body 200a is prepared. The support member 100a includes the plate-like part 110 extending along the XY plane, and the base part 120. The base part 120 includes the inclined surface 122 extending in a direction forming the angle θ from the plate surface 111.

The stacked body 200a includes the semiconductor chips 210-1 to 210-p. Each of the semiconductor chips 210-1 to 210-p includes the main surface 211 as the first surface, and the back surface 222 on a side opposite to the main surface 211. The electrode pad 240 is provided at the end parts 212 of the main surface 211 of each of the semiconductor chips 210-1 to 210-p.

First, the semiconductor chip 210-1 is placed on the inclined surface 122 of the support member 100a. As a result, the main surface 211 of the semiconductor chip 210-1 is inclined at the angle θ with respect to the plate surface 111. The back surface 222 of the semiconductor chip 210-1 is in contact with the inclined surface 122. Thus, the main surface 211 of the semiconductor chip 210-1 faces upward. The semiconductor chip 210-1 is disposed such that the end part 212 of the main surface 211 is positioned on the upper side of the inclined surface 122, and the end part 213 is positioned on the lower side of the inclined surface 122. The end part 215 of the back surface 222 of the semiconductor chip 210-1 is in contact with the plate surface 111.

Next, as illustrated in FIG. 2b, the semiconductor chip 210-2 is stacked directly above the semiconductor chip 210-1, namely, stacked on the negative direction side of X. The main surface 211 of the semiconductor chip 210-1 is in contact with the back surface 222 of the semiconductor chip 210-2. As a result, the main surface 211 of the semiconductor chip 210-2 is inclined at the angle θ with respect to the plate surface 111.

The semiconductor chip 210-2 is disposed such that the end part 212 is positioned on the upper side and the end part 213 is positioned on the lower side. At this time, the semiconductor chip 210-2 is shifted toward the end part 213 with respect to the semiconductor chip 210-1 such that the back surface 222 of the semiconductor chip 210-2 does not overlap the electrode pad 240 of the semiconductor chip 210-1.

The semiconductor chip 210-2 is shifted toward the end part 213 until the end part 215 of the back surface 222 is in contact with the plate surface 111. As a result, the electrode pad 240 of the semiconductor chip 210-1 and the electrode pad 240 of the semiconductor chip 210-2 are aligned on the plane SFA along the XY plane. This is because the length of one side along the XZ plane of the main surface 211 of each of the semiconductor chips 210-1 and 210-2 is substantially equal.

As illustrated in FIG. 2c, the semiconductor chip 210-3 is stacked directly above the semiconductor chip 210-2, that is, stacked on the negative direction side of X. The main surface 211 of the semiconductor chip 210-2 is in contact with the back surface 222 of the semiconductor chip 210-3. As a result, the main surface 211 of the semiconductor chip 210-3 is also inclined at the angle θ with respect to the plate surface 111.

The semiconductor chip 210-3 is disposed such that the end part 212 is positioned on the upper side and the end part 213 is positioned on the lower side. At this time, the semiconductor chip 210-3 is shifted toward the end part 213 with respect to the semiconductor chip 210-2 such that the back surface 222 of the semiconductor chip 210-3 does not overlap the electrode pad 240 of the semiconductor chip 210-2.

The semiconductor chip 210-3 is shifted toward the end part 213 until the end part 215 of the back surface 222 is in contact with the plate surface 111. As a result, the electrode pad 240 of the semiconductor chip 210-2 and the electrode pad 240 of the semiconductor chip 210-3 are aligned on the plane SFA along the XY plane. This is because the length of one side along the XZ plane of the main surface 211 of each of the semiconductor chips 210-2 and 210-3 is substantially equal.

In this manner, the fourth, fifth, and subsequent semiconductor chips 210 are sequentially placed on the semiconductor chip 210-3. As a result, the main surfaces 211 of the fourth, fifth, and subsequent semiconductor chips 210 are also inclined at the angle θ0 with respect to the plate surface 111.

The fourth, fifth, and subsequent semiconductor chips 210 are also shifted toward the end part 213 with respect to the semiconductor chip 210 located on the layer directly below, that is, on the positive direction side of X, until the end parts 215 of the back surfaces 222 are in contact with the plate surface 111.

Subsequently, the semiconductor chip 220 is disposed on the main surface 211 of the uppermost semiconductor chip 210. The semiconductor chip 220 is shifted with respect to the uppermost semiconductor chip 210 such that at least one of the electrode pads 250 provided on the main surface 221 is included in the plane SFA. With the processes described above, the stacked body 200a is formed.

Next, as illustrated in FIG. 3a, the sealing member 300a covering the stacked body 200a is formed. Specifically, for example, the uncured sealing member 300a is disposed on the bottom of a mold (not illustrated), the support member 100a is inverted upside down such that the plate surface 111 faces downward, and the support member 100a is inserted into the mold. Then, the entire mold is heated to cure the sealing member 300a, and then the mold is removed. As a result, the entire stacked body 200a is covered with the sealing member 300a. The surface 310a of the sealing member 300a, the surface 310a being close to the electrode pads 240 and 250, extends along the XY plane.

As illustrated in FIG. 3b, a resist pattern RP for forming the wiring layer 700 is formed on the surface 310a of the sealing member 300a. The resist pattern RP is obtained by exposing and developing a resist layer. The resist pattern RP has a wiring pattern extending in the XY plane.

Subsequently, the contact holes Hr are formed by irradiating the resist pattern RP with a laser or the like from above the resist pattern RP. The contact holes Hr extend from the surface 310a in the negative direction of Z through the sealing member 300a and respectively reach the metal bumps 600. The contact hole Hr is configured to be the vertical wire 400a at a later stage.

Note that the order of forming the resist pattern RP and the contact holes Hr is not limited to the above. For example, after forming the contact holes Hr, the resist layer (not illustrated) covering the contact holes Hr and the surface 310a may be formed, and the resist pattern RP may be formed by exposing and developing the resist layer.

Next, for example, by an electroless plating method, a plating layer MPa is formed to cover the contact holes Hr and openings of the resist pattern RP, as illustrated in FIG. 3c. The plating layer MPa includes, for example, a metal such as copper (Cu). As a result, the vertical wire 400a is formed in a part corresponding to the contact hole Hr. Note that, at this time, the plating layer MPa may also be partly formed on the upper surface of the resist pattern RP. Next, the resist pattern RP is removed by a lift-off method or the like. In this manner, the wiring layer 700 is formed on the surface 310a.

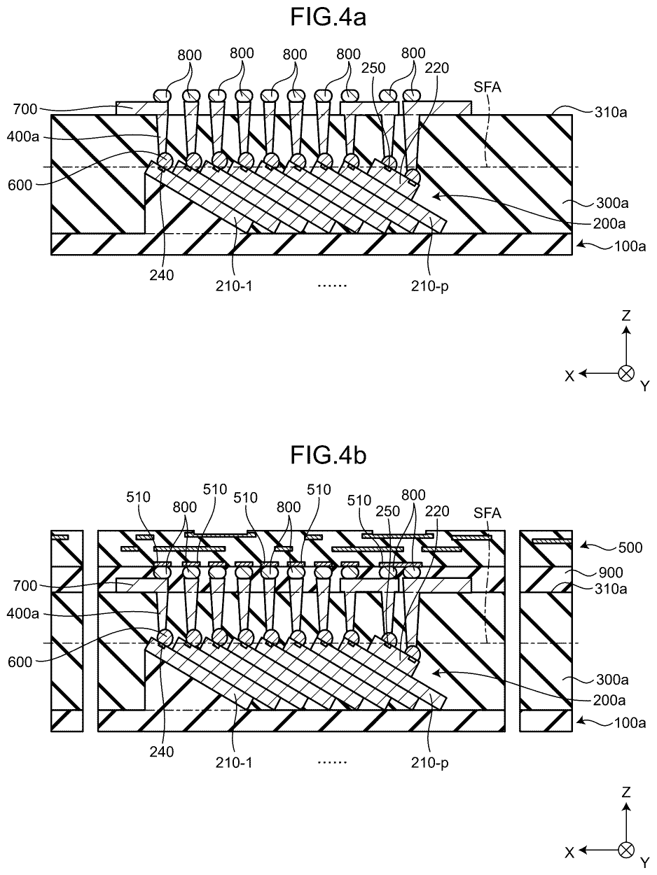

Next, as illustrated in FIG. 4a, the metal bumps 800 connected to the wiring layer 700 are formed. The metal bump 800 includes, for example, a metal such as copper (Cu) or gold (Au).

Next, as illustrated in FIG. 4b, the metal bumps 800 and the electrodes 510 provided on the lower surface of the wiring substrate 500 are vertically connected. Specifically, the electrodes 510 of the wiring substrate 500 and the metal bumps 800 are stacked vertically and heated to approximately 200° C. As a result, the molten metal bumps 800 are bonded to the electrodes 510, and the wiring substrate 500 is electrically connected to each of the semiconductor chips 210 and the semiconductor chip 220.

Thereafter, the space between the lower surface of the wiring substrate 500 and the surface 310 a is filled with the adhesive 900. Specifically, for example, by using at least one method among a coating method, an adhesion method, and a spraying method, a paste-like liquid, which is the uncured adhesive 900, is applied onto the lower surface of the wiring substrate 500, the side surfaces of the metal bumps 800, and the surface 310 a. Next, the adhesive 900 is cured by being heated, for example, in an oven or the like.

Next, the wiring substrate 500 is cut in the Z direction to perform dicing of the semiconductor device 1. In this manner, the manufacturing of the semiconductor device 1 according to the embodiment is completed.

However, the timing of the dicing is not limited thereto. For example, the wiring substrate 500 and the stacked body 200a may be diced in advance, and the diced wiring substrate 500 and the diced stacked body 200a may be electrically connected to each other.

### Comparative Example

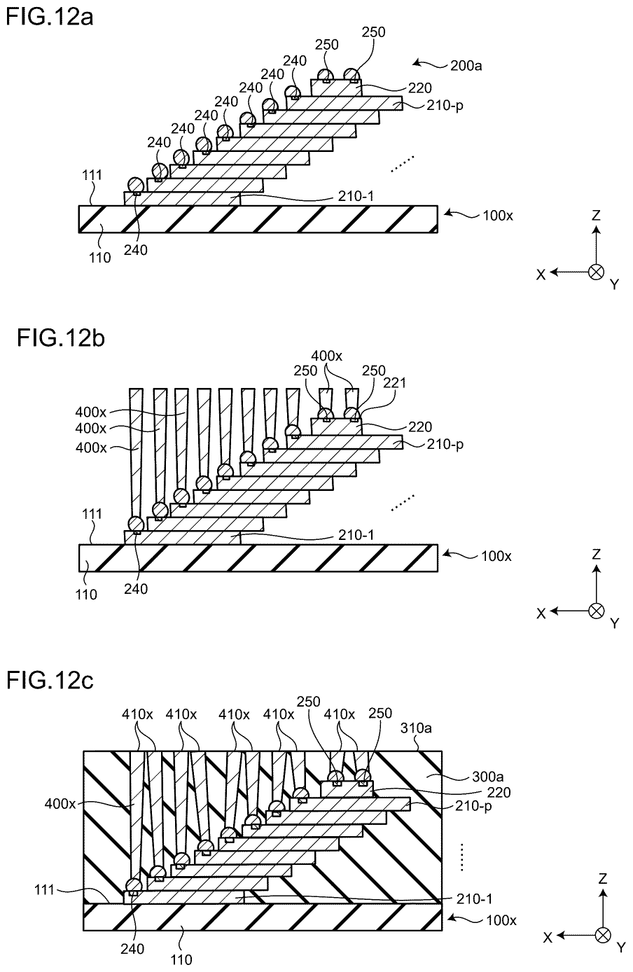

Next, the semiconductor device of a comparative example will be described with reference to FIGS. 12a, 12b, and 12c. FIGS. 12a to 12c are diagrams illustrating part of a procedure of a manufacturing method for the semiconductor device according to the comparative example.

As illustrated in FIG. 12a, in the manufacturing method for the semiconductor device of the comparative example, the inclined surface 122 is not formed on a support member 100x. The semiconductor chips 210 and the semiconductor chip 220 are stacked in parallel with the plate surface 111 while being, for example, shifted to the negative direction side of X. Therefore, the height positions of the electrode pads 240 when viewed from the plate surface 111 become higher in order from the lower layer side. The electrode pads 250 are positioned further above the electrode pads 240 of the uppermost layer.

Next, in the manufacturing method for the semiconductor device of the comparative example, as illustrated in FIG. 12b, vertical wires 400x, which are respectively connected to the electrode pads 240 and 250 and extend in the Z direction, are formed. Each of the vertical wires 400x reaches a position higher than the main surface 221 of the semiconductor chip 220, and the height positions of the respective upper end parts in the Z direction are substantially equal. Therefore, the vertical wire 400x extending from the semiconductor chip 210 on the lower layer side has a longer length. As the number of stacked semiconductor chips 210 and 220 is increased, the length of the vertical wire 400x is also increased. In a case where the length of the vertical wire 400x is increased, the electrical resistance of the vertical wire 400x rises, and thereby the electrical characteristics of the semiconductor device may deteriorate.

Moreover, in the manufacturing method for the semiconductor device of the comparative example, the sealing member 300a is not formed at the stage of forming the vertical wires 400x. Therefore, each of the vertical wires 400x extends in an atmosphere of gas or the like. Since the vertical wires 400x extending in the atmosphere are not fixed in position, the vertical wires 400x may interfere with each other. If some of the vertical wires 400x interfere with each other, the relevant semiconductor chips 210 or the interior of the semiconductor chip 220 may be short-circuited. Moreover, as the length of the vertical wire 400x is increased, the possibility of interference between the vertical wires 400x becomes higher. Therefore, also the possibility of the above-mentioned short-circuit may become higher.

As illustrated in FIG. 12c, in the manufacturing method for the semiconductor device of the comparative example, when forming the sealing member 300a, the positions of the vertical wires 400x may be shifted due to the contact with the sealing member 300a. If the positions of the vertical wires 400x are shifted, the exposed position of an upper end part 410x of the vertical wire 400x on the surface 310a may also be shifted. As a result, connection with the wiring substrate 500 may be difficult.

Furthermore, the vertical wire 400x may include, for example, gold (Au). The use of a relatively expensive metal such as Au may cause increase in production cost.

### Overview

In contrast to the above-described comparative example, the stacked body 200a of the semiconductor device 1 according to the embodiment includes the semiconductor chips 210-1 to 210-3, which are arranged such that the main surfaces 211 are inclined with respect to the wiring substrate 500. The semiconductor chip 210-2 is stacked directly above the semiconductor chip 210-1, on the negative direction side of X so as not to overlap the electrode pad 240 of the semiconductor chip 210-1, and the semiconductor chip 210-3 is stacked directly above the semiconductor chip 210-2, on the negative direction side of X so as not to overlap the electrode pad 240 of the semiconductor chip 210-2. As a result, among the semiconductor chips 210-1 to 210-3, the electrode pads 240 of at least two semiconductor chips are included in the plane SFA.

The sealing member 300a includes the surface 310a, which is substantially parallel to the plane SFA, on the side close to the electrode pad 240. The vertical wires 400a extend from the respective electrode pads 240 in a direction perpendicular to the surface 310a and is exposed on the surface 310a. As a result, the distance between the plane SFA and the surface 310a becomes uniformly short. Therefore, the vertical wires 400a can be easily led out onto the surface 310a. In addition, the lengths of the vertical wires 400a extending between the plane SFA and the surface 310a are uniformly short. Therefore, the electrical resistance in the vertical wire 400a is reduced, and thereby the electrical characteristics of the semiconductor device 1 are improved.

Each of the semiconductor chips 210 and the semiconductor chip 220 is stacked in an inclined manner such that the end part 212 is positioned above the end part 213. The angle θ between the wiring substrate 500 and each of the semiconductor chips 210 and the semiconductor chip 220 is in a range of 3 degrees to 30 degrees, both inclusive. As a result, the height of each of the semiconductor chips 210 and the semiconductor chip 220 in the Z direction can be set to be equal to or less than a predetermined value.

Note that it is desirable that each of the semiconductor chips 210 and the semiconductor chip 220 has an elongated rectangular shape with short sides along the XZ plane and long sides along the YZ plane. This is because the height in the Z direction of each of the semiconductor chips 210 and the semiconductor chip 220, which are arranged in an inclined manner on the upper surface of the support member 100a, is the height corresponding to the length of one side along the XZ plane of each semiconductor chip. By shortening the length of one side along the XZ plane of each semiconductor chip, the height of each of the semiconductor chips 210 and the semiconductor chip 220 in the Z direction can be reduced, and as a result, the semiconductor device 1 can be made thinner.

In the manufacturing method for the semiconductor device according to the embodiment, after the sealing member 300a is formed, the vertical wires 400a extending through the sealing member 300a are formed. Since the position of each of the vertical wires 400a is fixed by the sealing member 300a, the interference between the vertical wires 400a can be prevented. The semiconductor chips 210 and the semiconductor chips 220 can be prevented from being short-circuited. In addition, since the displacement of the positions of the vertical wires 400a can be prevented, the difficulty of electrically connecting the vertical wires 400a to the wiring substrate 500 can be reduced.

Moreover, after forming the sealing member 300a, the vertical wires 400a extending through the sealing member 300a is formed. Therefore, a plating method can be used for forming the vertical wires 400a. By using the plating method, a relatively inexpensive metal such as copper (Cu) can be used as the material for the vertical wires 400a. As a result, the production cost can be reduced.

### First Modification Example

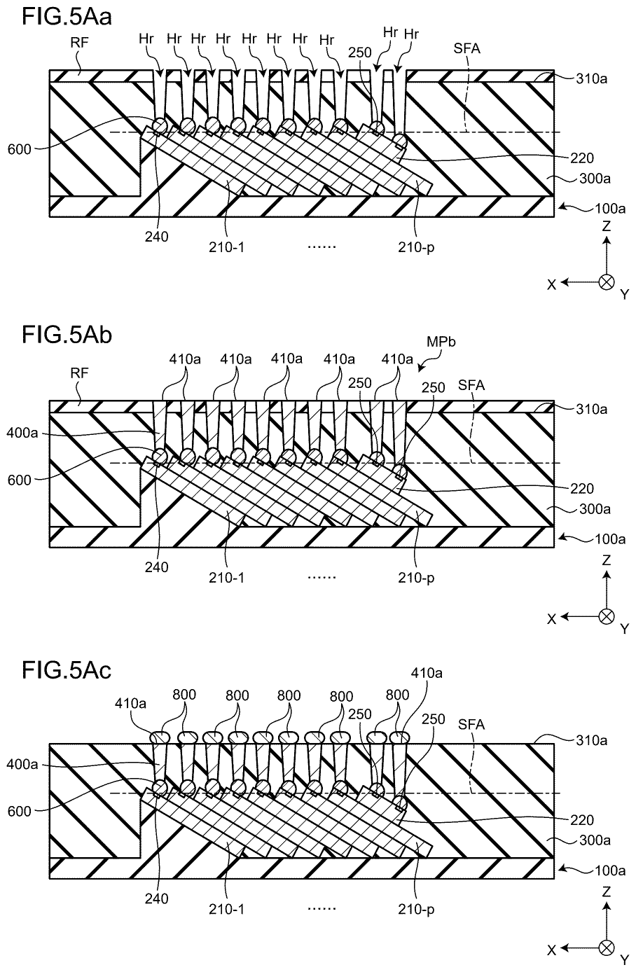

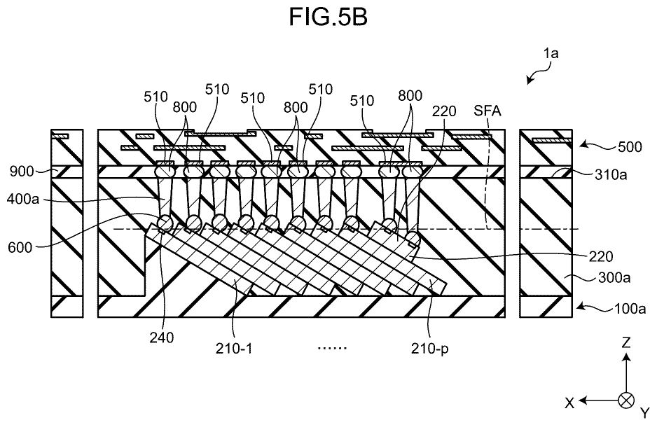

A manufacturing method for a semiconductor device 1a of a first modification example of the embodiment will be described with reference to FIG. 5Aa, 5Ab, 5Ac, and 5B. The manufacturing method for the semiconductor device 1a of the first modification example is different from the above-described embodiment in that the wiring layer 700 is not formed.

Note that in the following description, the same reference numerals are given to the same configurations as those in the above-described embodiment, and detailed descriptions thereof may be omitted.

FIG. 5Aa, 5Ab, 5Ac, and 5B are diagrams sequentially illustrating part of a procedure of the manufacturing method for the semiconductor device 1a according to the first modification example of the embodiment.

Prior to FIG. 5Aa, in the manufacturing method for the semiconductor device 1a of the first modification example, the processing up to FIG. 3a of the above-described embodiment is performed.

As illustrated in FIG. 5Aa, a resist layer RF covering the surface 310a of the sealing member 300a is formed. By covering the surface 310a with the resist layer RF, the adhesion of a plating layer MPb onto the surface 310a during the subsequent formation of the vertical wires 400a can be suppressed. After the resist layer RF is formed, the contact holes Hr are formed by irradiating the resist layer RF with a laser or the like from above the resist layer RF.

Next, for example, by using an electroless plating method, the plating layer MPb is formed to cover the contact holes Hr, as illustrated in FIG. 5Ab. As a result, the vertical wires 400a are formed in places where the contact holes Hr are formed. Note that, at this time, the plating layer MPb may also be partly formed on the upper surface of the resist layer RF.

Next, the resist layer RF formed on the surface 310a is removed by a lift-off method or the like. At this time, in a case where the upper end part 410a of the vertical wire 400a protrudes above the surface 310a, for example, the vertical wire 400a may be ground from above by using a Chemical Mechanical Polishing (CMP) method or the like, and the height positions of the surface 310a and the upper end part 410a of the vertical wire 400a may be aligned.

Next, as illustrated in FIG. 5Ac, the metal bumps 800 connected to the upper end parts 410a of the vertical wires 400a are formed.

After FIG. 5Ac, the processing subsequent to FIG. 4b of the embodiment is performed. In this manner, the semiconductor device 1a illustrated in FIG. 5B is formed. As described above, the manufacturing of the semiconductor device 1a of the first modification example is completed.

With the manufacturing method for the semiconductor device 1a of the first modification example, a semiconductor device having the same effects as the semiconductor device 1 of the embodiment can be obtained.

### Second Modification Example

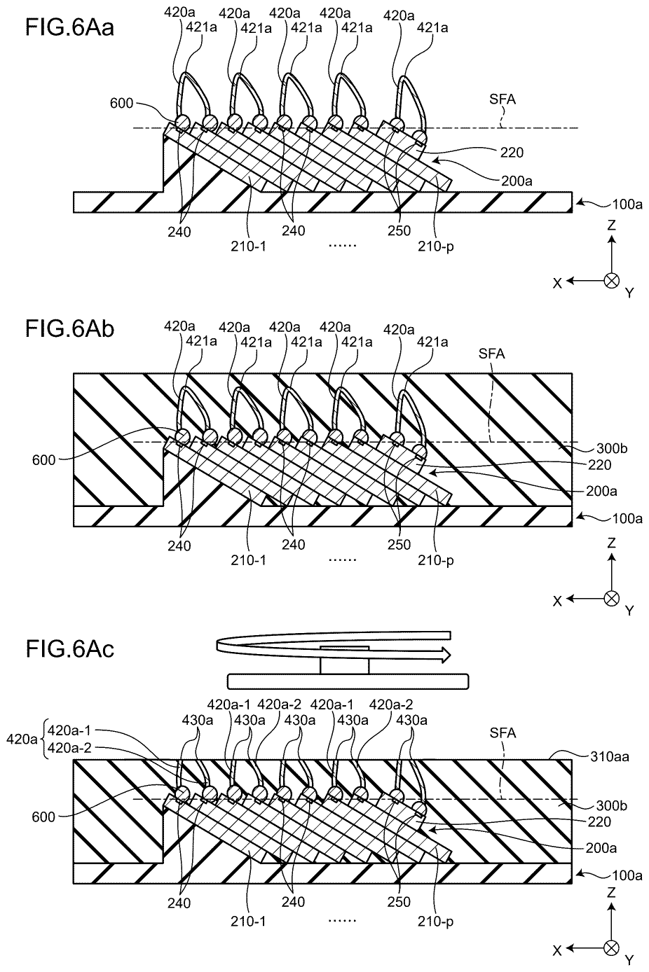

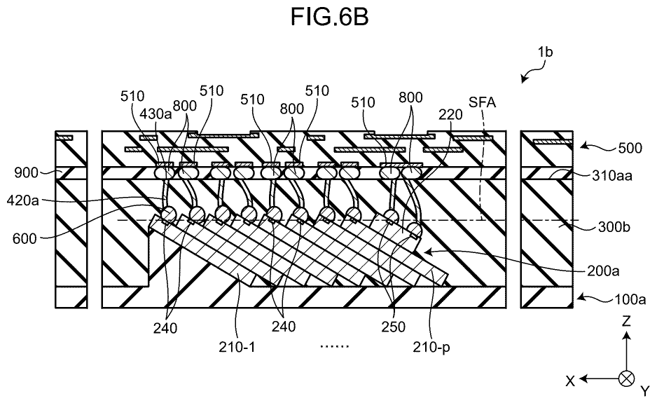

A manufacturing method for a semiconductor device 1b of a second modification example of the embodiment will be described with reference to FIG. 6Aa, 6Ab, 6Ac, and 6B. In the manufacturing method for the semiconductor device 1b of the second modification example, the point that a wire 420a is used as the through electrode instead of the vertical wire 400a differs from the above-described embodiment.

Note that in the following description, the same reference numerals are given to the same configurations as those in the above-described embodiment, and detailed descriptions thereof may be omitted.

FIG. 6Aa, 6Ab, 6Ac, and 6B are diagrams sequentially illustrating part of a procedure of the manufacturing method for the semiconductor device 1b according to the second modification example of the embodiment.

Prior to FIG. 6Aa, in the manufacturing method for the semiconductor device 1b of the second modification example, the processing up to FIG. 2c of the above-described embodiment is performed.

As illustrated in FIG. 6Aa, wires 420a are formed to connect the vertically adjacent electrode pads 240 to each other and connect the electrode pads 250 provided on the semiconductor chip 220 to each other. In other words, among the wires 420a, some wires 420a connect the electrode pads 240 vertically adjacent to each other, and some wires 420a connect the electrode pads 250 to each other.

Among the wires 420a, some wires 420a extend from the metal bumps 600 covering any of the electrode pads 240 in the positive direction of Z. These wires 420a are curved and folded back at upper end parts 421a thereof and are connected to the metal bumps 600 covering the adjacent electrode pad 240. Moreover, some wires 420a extend from the metal bumps 600 covering one electrode pad 250 in the positive direction of Z. These wires 420a are curved and folded back at the upper end parts 421a and are connected to the metal bumps 600 covering the other electrode pad 250.

The wire 420a is formed by a wire bonding method. The upper end part 421a is an example of the folded part. The positive direction of Z is an example of the second direction.

Next, as illustrated in FIG. 6Ab, a sealing member 300b that covers the entire stacked body 200a including the wires 420a is formed. However, at this stage, the wires 420a are not exposed from the sealing member 300b, and thus the sealing member 300b is not provided with the surface 310a.

Next, for example, by using a CMP method or the like, the sealing member 300b is ground from above, that is, from the positive direction side of Z, until the upper end parts 421a of the wires 420a are cut off. As illustrated in FIG. 6Ac, the sealing member 300b is ground until the upper end parts 421a are removed and the wires 420a are separated into a wire 420a-1 and a wire 420a-2. As a result, the height of the sealing member 300b is reduced to form a surface 310aa, and on this surface 310aa, an end part 430a of each of the wire 420a-1 and the wire 420a-2 is exposed. The surface 310aa is a surface parallel to the plane SFA. The surface 310aa is an example of the third surface.

After FIG. 6Ac, the processing subsequent to FIG. 5Ac of the first modification example is performed. However, in the second modification example, the metal bump 800 is formed to be connected to the end part 430a of each of the wire 420a-1 and the wire 420a-2. In this manner, the semiconductor device 1b as illustrated in FIG. 6B is formed. As described above, the manufacturing of the semiconductor device 1b of the second modification example is completed.

With the manufacturing method for the semiconductor device 1b of the second modification example, a semiconductor device having the same effects as the semiconductor device 1 of the embodiment can be obtained.

### Third Modification Example

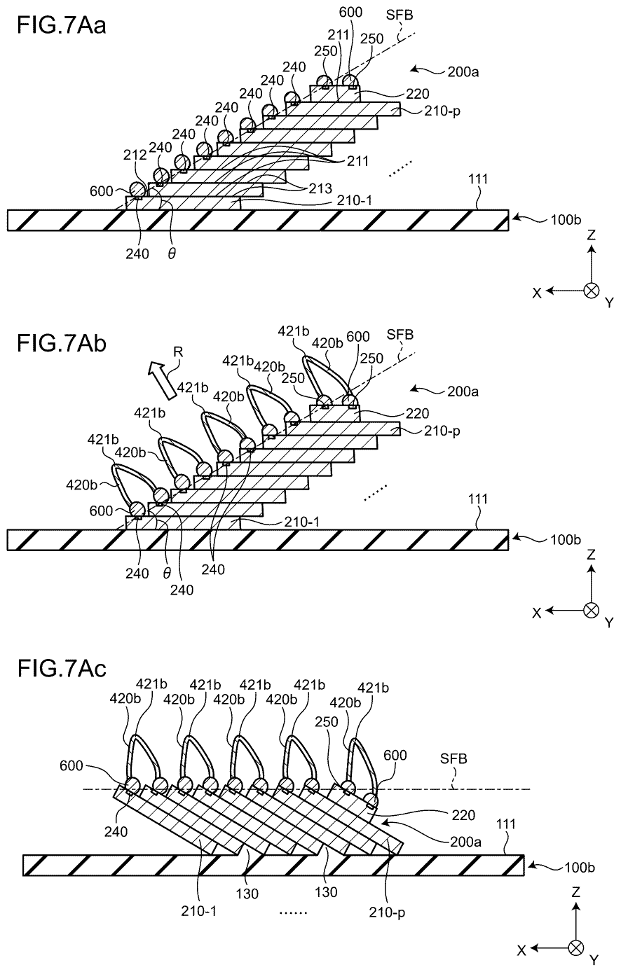

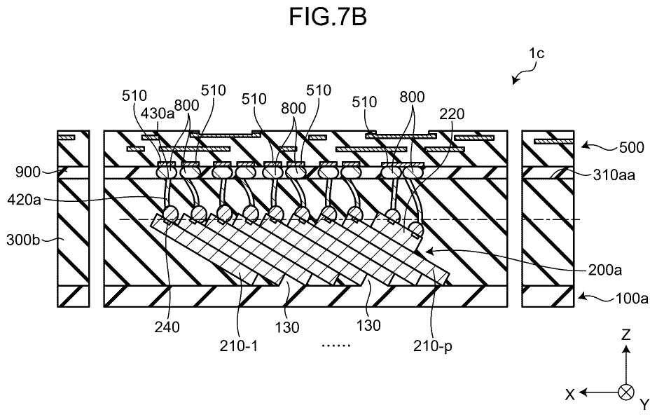

A manufacturing method for a semiconductor device 1c of a third modification example of the embodiment will be described with reference to FIG. 7Aa to 7B. The manufacturing method for the semiconductor device 1c according to the third modification example is a modification example corresponding to the second modification example, and the procedure from the disposition of the stacked body 200a on a support member 100b to the sealing is different from those of the above-described embodiment and the second modification example.

Note that in the following description, the same reference numerals are given to the same configurations as those in the above-described embodiment and the modification example, and detailed descriptions thereof may be omitted.

FIG. 7Aa to 7B are diagrams sequentially illustrating part of a procedure of the manufacturing method for the semiconductor device 1c according to the third modification example of the embodiment.

As illustrated in FIG. 7Aa, the inclined surface 122 is not formed on the support member 100b of the semiconductor device 1c according to the third modification example. The semiconductor chips 210 and the semiconductor chip 220 are stacked in parallel with the plate surface 111 while being, for example, shifted to the negative direction side of X. In this manner, the stacked body 200a is formed.

The plate surface 111 overlaps with the back surface 222 of the semiconductor chip 210-1. When stacking the semiconductor chip 210-2, the semiconductor chip 210-3, and the subsequent chips, on the semiconductor chip 210-1 that is in contact with the plate surface 111, the amount of shift with respect to the semiconductor chip 210 directly below is adjusted such that each of the electrode pads 240 provided at the end parts 212 of the main surfaces 211 is included on the same plane SFB. The plane SFB extends in a direction forming the angle θ with respect to the plate surface 111. The direction forming the angle θ with respect to the plate surface 111 is an example of the third direction.

Next, as illustrated in FIG. 7Ab, wires 420b are formed to connect the vertically adjacent electrode pads 240 to each other and connect the electrode pads 250 to each other.

Among the wires 420b, some wires 420b extend from the metal bumps 600 covering any of the electrode pads 240 in a direction of an arrow R of FIG. 7Ab. These wires 420b are curved and folded back at upper end parts 421b thereof and are connected to the metal bumps 600 covering the adjacent electrode pad 240. Moreover, some wires 420b extend from the metal bumps 600 covering one electrode pad 250 in a direction of the arrow R. These wires 420b are curved and folded back at the upper end parts 421b and are connected to the metal bumps 600 covering the other electrode pad 250. The direction of the arrow R is a direction perpendicular to the plane SFB. Thus, the direction of the arrow R is the directions of +X and +Z in FIG. 7Ab. The direction of the arrow R is an example of the fourth direction. The upper end part 421b is an example of the folded part.

Next, the entire stacked body 200a is separated from the support member 100b by detachment of the semiconductor chip 210-1 from the plate surface 111. Thereafter, as illustrated in FIG. 7Ac, the stacked body 200a is inclined such that the plane SFB becomes parallel to the plate surface 111, and the inclined stacked body 200a is rearranged on the plate surface 111. As a result, the electrode pads 240 and 250 are arranged at substantially the same height position when viewed from the plate surface 111, and each of the wires 420b extending from the respective electrode pads extends in the positive direction of Z. The plate surface 111 is an example of the upper surface of the support member 100b.

Note that, as illustrated in FIG. 7Ac, for propping up the inclined stacked body 200a, one or more projections 130 may be provided on the plate surface 111 of the support member 100b, on which the stacked body 200a is rearranged.

After FIG. 7Ac, the processing subsequent to FIG. 6Ab of the above-described second modification example is performed. In this manner, the semiconductor device 1c as illustrated in FIG. 7B is formed. As described above, the manufacturing of the semiconductor device 1c of the third modification example is completed.

With the manufacturing method for the semiconductor device 1c of the third modification example, a semiconductor device having the same effects as the semiconductor device 1 of the embodiment can be obtained.

### Fourth Modification Example

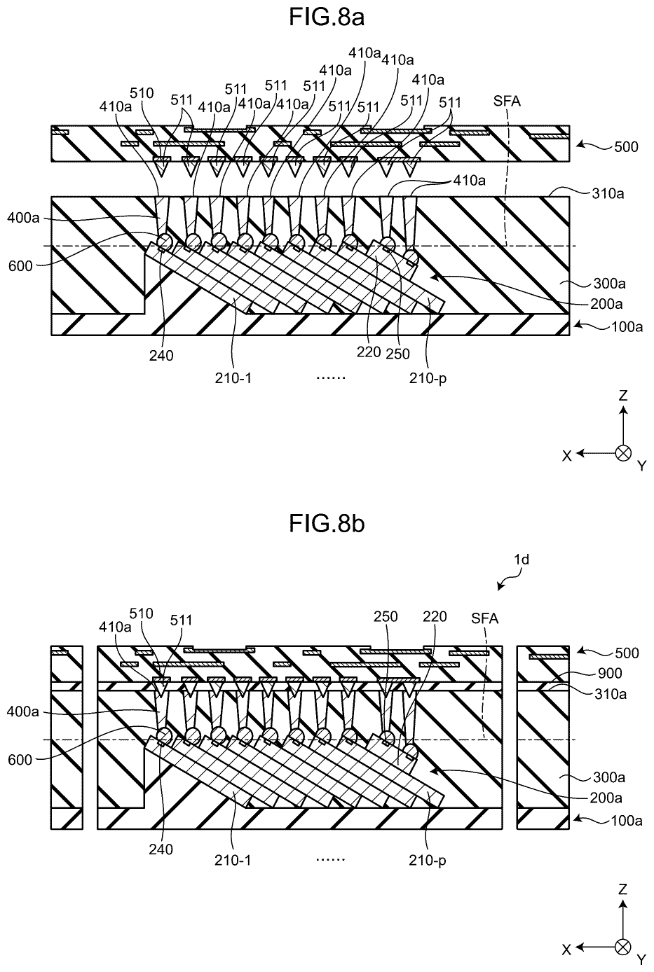

A manufacturing method for a semiconductor device 1d of a fourth modification example of the embodiment will be described with reference to FIGS. 8a and 8b. The manufacturing method for the semiconductor device 1d of the fourth modification example is a modification example corresponding to the first modification example, and is different from the above-described embodiment and the first modification example in that the metal bumps 800 are not formed.

Note that in the following description, the same reference numerals are given to the same configurations as those in the above-described embodiment and the modification example, and detailed descriptions thereof may be omitted.

FIGS. 8a and 8b are diagrams sequentially illustrating part of a procedure of the manufacturing method for the semiconductor device 1d according to the fourth modification example of the embodiment.

Prior to FIG. 8a, in the manufacturing method for the semiconductor device 1d of the fourth modification example, the processing up to FIG. 5Ab of the above-described first modification example is performed.

As illustrated in FIG. 8a, a projection 511 protruding downward is formed on each electrode 510 provided on the lower surface of the wiring substrate 500. The projection 511 is formed in a wedge shape. The projection 511 includes, for example, Steel special Use Stainless (SUS) including nickel (Ni).

Note that the projection 511 does not necessarily include SUS, and may simply include a metal having a higher hardness than metals such as copper (Cu) included in the vertical wire 400a.

As illustrated in FIG. 8b, the projections 511 and the upper end parts 410a of the vertical wires 400a are vertically faced with each other, and the wiring substrate 500 is pressed against the surface 310a. As a result, the projections 511 are inserted into the upper end parts 410a of the vertical wires 400a. At this time, stress to return upward acts on the metal included in the vertical wire 400a, which is pressed downward by the projection 511. Due to such stress in the metal, the projections 511 and the vertical wires 400a are more reliably connected.

In this manner, the wiring substrate 500 and the vertical wires 400a can be electrically connected without using the metal bumps 800. As described above, the metal bumps 800 of the embodiment are heated to approximately 200° C. in order to melt solder during the bonding with the electrodes 510. Due to the heating of the metal bumps 800, the temperature of the surrounding configuration such as the wiring substrate 500 may also be increased. By providing the projections 511, thermal effects on each configuration can be reduced.

After the space between the lower surface of the wiring substrate 500 and the surface 310a is filled with the adhesive 900, the wiring substrate 500 is cut in the Z direction to perform dicing of the semiconductor device 1d. In this way, the manufacturing of the semiconductor device 1d of the fourth modification example is completed.

With the manufacturing method for the semiconductor device 1d of the fourth modification example, a semiconductor device having the same effects as the semiconductor device 1 of the embodiment can also be obtained.

### Fifth Modification Example

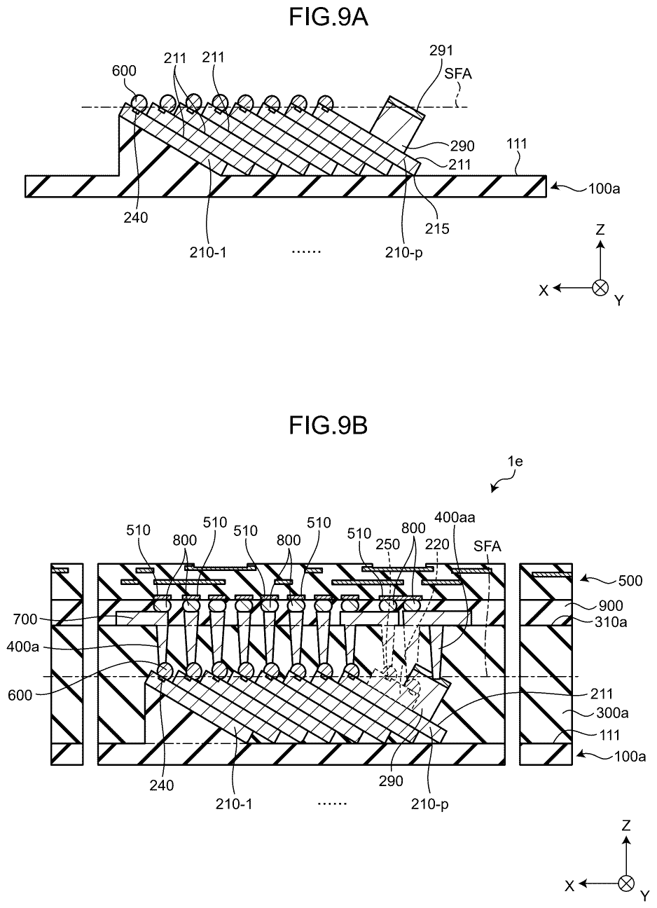

A manufacturing method for a semiconductor device 1e of a fifth modification example of the embodiment will be described with reference to FIGS. 9A and 9B. The manufacturing method for the semiconductor device 1e of the fifth modification example is different from the above-described embodiment in that a passive component is further stacked on the semiconductor chip 220.

Note that, in the following description, the same reference numerals are given to the same configurations as those in the above-described embodiment and the modification example, and detailed descriptions thereof may be omitted.

FIGS. 9A and 9B are diagrams sequentially illustrating part of a procedure of the manufacturing method for the semiconductor device 1e according to the fifth modification example of the embodiment. Note that, in FIG. 9B, a cross section including the semiconductor chip 220 and a cross section including a passive component 290 are superimposed for convenience of illustration.

Prior to FIG. 9A, in the manufacturing method for the semiconductor device 1e of the fifth modification example, the processing up to FIG. 2c of the above-described embodiment is performed.

As illustrated in FIG. 9A, in a process of forming the stacked body 200a, the passive component 290 is arranged in a region on the main surface 211 of the uppermost semiconductor chip 210 where the semiconductor chip 220 is not arranged. The passive component 290 is, for example, a capacitor or the like. A surface of the passive component 290 on a side opposite to the uppermost semiconductor chip 210 is covered by an electrode layer 291. The passive component 290 is appropriately shifted with respect to the uppermost semiconductor chip 210 such that the electrode layer 291 is included in the plane SFA.

Note that the passive component 290 is not necessarily disposed on the main surface 211 of the uppermost semiconductor chip 210, and may be disposed on the main surface 221 of the semiconductor chip 220, for example. In FIGS. 9A and 9B, it is assumed that the semiconductor chip 220 and the passive component 290 are not included in the same cross section, but the present invention is not limited thereto. The semiconductor chip 220 and the passive component 290 may be included in the same cross section.

After FIG. 9A, the processing subsequent to FIG. 3a of the above-described embodiment is performed. However, in the fifth modification example, a vertical wire 400aa is also formed. The vertical wire 400aa is connected to the electrode layer 291 of the passive component 290 at the lower end part thereof. The vertical wire 400aa extends upward through the sealing member 300a and is exposed on the surface 310a. In this manner, the semiconductor device 1e illustrated in FIG. 9B is formed. As described above, the manufacturing of the semiconductor device 1e of the fifth modification example is completed.

With the manufacturing method for the semiconductor device 1e of the fifth modification example, a semiconductor device having the same effects as the semiconductor device 1 of the embodiment can be obtained.

### Sixth Modification Example

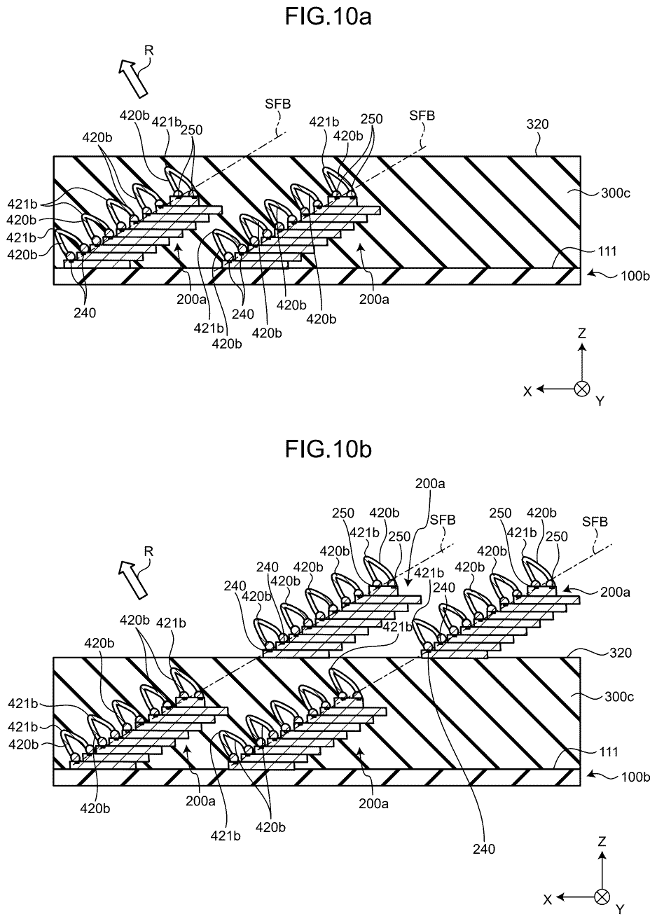

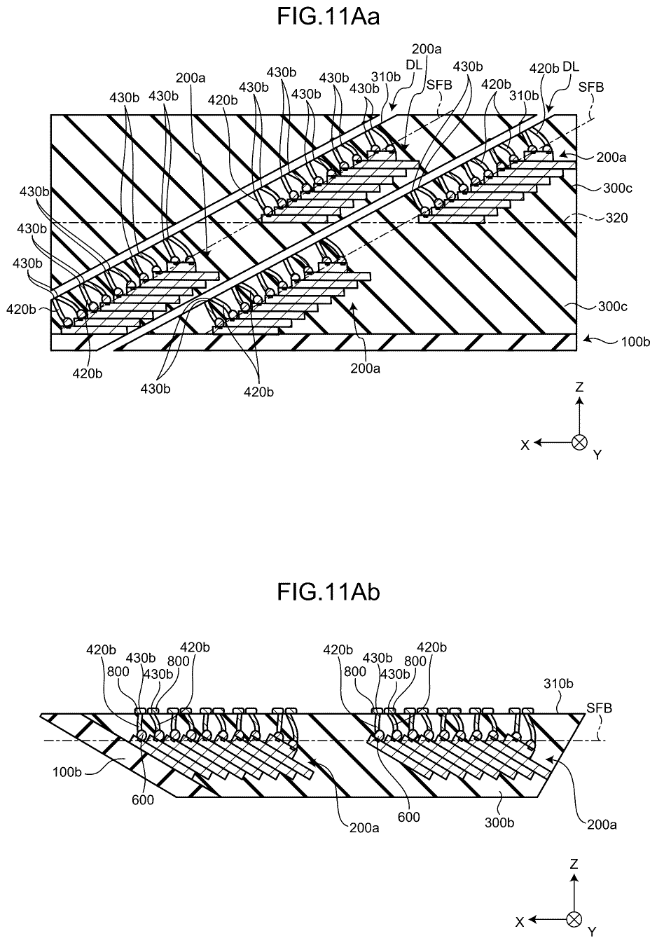

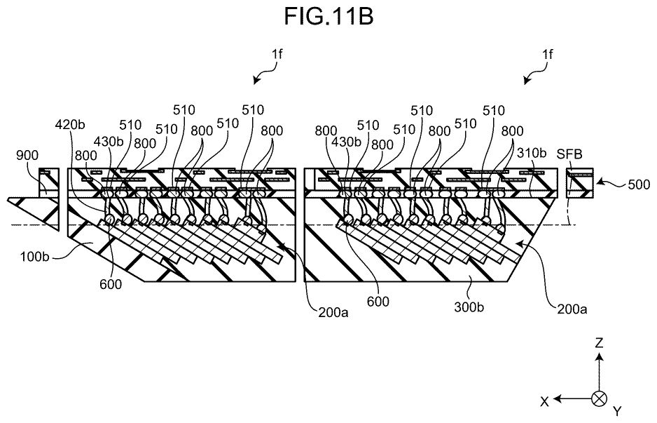

A manufacturing method for a semiconductor device 1f of a sixth modification example of the embodiment will be described with reference to FIGS. 10a, 10b, 11Aa, 11Ab, and 11B. The manufacturing method for the semiconductor device 1f of the sixth modification example is a modification example of the third modification example, and is different from the above-described embodiment and the third modification example in that the stacked bodies 200a sealed by a sealing member 300c are stacked in the Z direction.

Note that, in the following description, the same reference numerals are given to the same configurations as those in the above-described embodiment and the modification example, and detailed descriptions thereof may be omitted.

FIGS. 10a, 10b, 11Aa, 11Ab, and 11B are diagrams sequentially illustrating part of a procedure of the manufacturing method for the semiconductor device 1f according to the sixth modification example of the embodiment.

Prior to FIG. 10a, in the manufacturing method for the semiconductor device 1f of the sixth modification example, the processing up to FIG. 7Ab of the above-described third modification example is performed. Specifically, the semiconductor chips 210 and the semiconductor chip 220, which are stacked in parallel with the plate surface 111 while being shifted to the negative direction side of X, are formed as first-layer stacked bodies 200a on the plate surface 111 of the support member 100b. The respective electrode pads 240 and 250 of the semiconductor chips 210 and the semiconductor chip 220 are included on the same plane SFB.

In each of the first-layer stacked bodies 200a, the wires 420b connecting the electrode pads 240 to each other and the electrode pads 250 to each other are formed. The wires 420b extend in the direction of the arrow R perpendicular to the plane SFB, and are curved and folded back at the upper end parts 421b thereof.

As illustrated in FIG. 10a, the first-layer sealing member 300c is formed to cover the entire stacked bodies 200a including the wires 420b. At this stage, the sealing member 300c includes a surface 320 on the upper side. The wires 420b are not exposed on the surface 320. Thus, the sealing member 300c is not provided with the surface 310a.

Next, as illustrated in FIG. 10b, second-layer stacked bodies 200a are arranged on the surface 320. Specifically, the semiconductor chips 210 and the semiconductor chip 220, which are stacked in parallel with the surface 320 while being shifted to the negative direction side of X, are formed as second-layer stacked bodies 200a on the surface 320. At this time, the arrangement positions of the second-layer stacked bodies 200a are adjusted such that the electrode pads 240 and 250 thereof are included on the same plane as the plane SFB.

The wires 420b extending in the direction of the arrow R are also formed in each of the second-layer stacked bodies 200a. Thereafter, the second-layer sealing member 300c covering the entire second-layer stacked bodies 200a including the wires 420b is formed.

Next, as illustrated in FIG. 11Aa, the first-layer and second-layer sealing members 300c are cut along dicing lines DL along the plane SFB. The dicing lines DL pass through positions where the upper end parts 421b of the wires 420b are cut. As a result, a surface 310b is formed on the sealing member 300c, and end parts 430b of the wires 420b are exposed on the surface 310b.

After FIG. 11Aa, the processing subsequent to FIG. 5Ac of the above-described first modification example is performed. Specifically, as illustrated in FIG. 11Ab, the metal bumps 800 are formed to be connected to the end parts 430b of the wires 420b. Thereafter, the processing subsequent to FIG. 6Ac of the above-described second modification example is performed. In this manner, the semiconductor device 1f as illustrated in FIG. 11B is formed. The manufacturing of the semiconductor device 1f of the sixth modification example is completed.

With the manufacturing method for the semiconductor device 1f of the sixth modification example, a larger number of semiconductor devices 1f can be cut out from the sealing member 300c before dicing. In addition, a semiconductor device having the same effects as the semiconductor device 1 of the embodiment can also be obtained.

### Other Modification Examples

In the above-described embodiment and modification examples, the support members 100a and 100b each include a resin material, but the present disclosure is not limited thereto. For example, the support members 100a and 100b may each include a material similar to that of the wiring substrate 500. By configuring the support members 100a and 100b similarly to the wiring substrate 500, the thermal expansion rates of the support members 100a and 100b and the wiring substrate 500 are substantially equal. The thermal expansion rates of the support members 100a and 100b and the wiring substrate 500, which are arranged facing each other in the Z direction, are substantially equal. Therefore, stresses caused by expansion and contraction thereof are suppressed, and thereby warpage or the like of the semiconductor device 1 can be suppressed.

While certain embodiments have been described, these embodiments have been presented by way of example only, and are not intended to limit the scope of the inventions. Indeed, the novel embodiments described herein may be embodied in a variety of other forms; moreover, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a wiring substrate;
a stacked body including first to third semiconductor chips, each of the first to third semiconductor chips including a first surface and a second surface on a side opposite to the first surface, each of the first to third semiconductor chips being arranged to cause the first surface to face the wiring substrate with an inclination, each of the first to third semiconductor chips including an electrode pad on an end part of the first surface, the second semiconductor chip being stacked directly above the first semiconductor chip in a first direction along the wiring substrate without overlap between the second surface of the second semiconductor chip and the electrode pad of the first semiconductor chip, the third semiconductor chip being stacked directly above the second semiconductor chip in the first direction without overlap between the second surface of the third semiconductor chip and the electrode pad of the second semiconductor chip;
a sealing member covering the stacked body and including a third surface on a side close to the electrode pad of the stacked body, the third surface being parallel to a plane in which the electrode pads of at least two of the first to third semiconductor chips are included; and
a plurality of through electrodes extending from the electrode pad in a second direction perpendicular to the third surface through the sealing member and being connected to the wiring substrate.

2. The semiconductor device according to claim 1, wherein an angle of the inclination of the first surface of each of the first to third semiconductor chips with respect to the wiring substrate is in a range of 3 degrees to 30 degrees, both inclusive.

3. The semiconductor device according to claim 1, wherein the through electrodes each include copper (Cu).

4. The semiconductor device according to claim 1, further comprising a wiring layer extending in parallel to the third surface of the sealing member and connecting the through electrodes and the wiring substrate.

5. The semiconductor device according to claim 1, wherein
the wiring substrate includes a wedge-shaped projection on a surface facing the third surface of the sealing member, and
the through electrodes and the wiring substrate are connected through the wedge-shaped projection.

6. A manufacturing method for a semiconductor device, the manufacturing method comprising:
forming a stacked body including first to third semiconductor chips, each of the first to third semiconductor chips including a first surface and a second surface on a side opposite to the first surface, each of the first to third semiconductor chips including an electrode pad on an end part of the first surface, the second semiconductor chip being stacked directly above the first semiconductor chip in a first direction along the wiring substrate without overlap between the second surface of the second semiconductor chip and the electrode pad of the first semiconductor chip, the third semiconductor chip being stacked directly above the second semiconductor chip in the first direction without overlap between the second surface of the third semiconductor chip and the electrode pad of the second semiconductor chip;
forming a sealing member to cover the stacked body and include a third surface on a side close to the electrode pad of the stacked body, the third surface being parallel to a plane in which the electrode pads of at least two of the first to third semiconductor chips are included;
forming a through electrode to extend from the electrode pad in a second direction perpendicular to the third surface through the sealing member and to be connected to the wiring substrate; and
connecting the through electrode and a wiring substrate in the second direction.

7. A manufacturing method for a semiconductor device, the manufacturing method comprising:
forming a stacked body including first to third semiconductor chips, each of the first to third semiconductor chips including a first surface and a second surface on a side opposite to the first surface, each of the first to third semiconductor chips including an electrode pad on an end part of the first surface, the second semiconductor chip being stacked directly above the first semiconductor chip in a first direction along the wiring substrate without overlap between the second surface of the second semiconductor chip and the electrode pad of the first semiconductor chip, the third semiconductor chip being stacked directly above the second semiconductor chip in the first direction without overlap between the second surface of the third semiconductor chip and the electrode pad of the second semiconductor chip;
forming a wire to connect two adjacent electrode pads and include a folded part on a side of a second direction perpendicular to a plane in which the electrode pads of at least two of the first to third semiconductor chips are included;
forming a sealing member to cover the stacked body and the wire;
exposing an end part of the wire on a third surface parallel to the plane by cutting the sealing member from the second direction side until the folded part is cut off; and
connecting the end part of the wire and a wiring substrate in the second direction.

8. The manufacturing method according to claim 7, wherein
the forming of the stacked body includes arranging the first semiconductor chip on an upper surface of a support member to overlap the second surface of the first semiconductor chip onto the upper surface, and
the forming of the wire includes
forming the wire including the folded part in a fourth direction perpendicular to the plane extending in the third direction, the third direction forming an angle with respect to the upper surface of the support member, and,
before the forming of the sealing member,
separating the stacked body including the first semiconductor chip from the upper surface of the support member, and
rearranging the stacked body on the upper surface of the support member such that the plane extends along a plane perpendicular to the second direction.

9. The manufacturing method according to claim 6, wherein the forming of the stacked body includes arranging the first to third semiconductor chips on an upper surface of a support member such that the first surfaces of the first to third semiconductor chips are inclined with respect to the upper surface of the support member.

10. The manufacturing method according to claim 9, wherein an angle of inclination of the first surface of each of the first to third semiconductor chips with respect to the upper surface is in a range of 3 degrees to 30 degrees, both inclusive.

11. The manufacturing method according to claim 6, wherein the through electrode includes copper (Cu).

12. The manufacturing method according to claim 6, wherein the connecting of the through electrode and the wiring substrate in the second direction includes forming a wiring layer to extend in parallel to the third surface and connect the through electrode and the wiring substrate.

13. The manufacturing method according to claim 6, wherein the connecting of the through electrode and the wiring substrate in the second direction includes connecting the through electrode and the wiring substrate through a wedge-shaped projection formed on a surface of the wiring substrate facing the third surface.

14. The manufacturing method according to claim 7, wherein the forming of the stacked body includes arranging the first to third semiconductor chips on an upper surface of a support member such that the first surfaces of the first to third semiconductor chips are inclined with respect to the upper surface of the support member.

15. The manufacturing method according to claim 14, wherein an angle of inclination of the first surface of each of the first to third semiconductor chips with respect to the upper surface is in a range of 3 degrees to 30 degrees, both inclusive.
